(19) United States
(12) Patent Application Publication
(10) Pub. No.: US 2017/0229371 A1
(43) Pub. Date: Aug. 10, 2017

(54) ELECTRONIC DEVICE

(71) Applicant: DENSO CORPORATION, Kariya-city, Aichi-pref. (JP)

(72) Inventor: Shinji HIRAMITSU, Kariya-city (JP)

(21) Appl. No.: 15/502,645

(22) PCT Filed: Feb. 8, 2016
(86) PCT No.: PCT/JP2016/000632

§ 371 Date: Feb. 8, 2017

(30) Foreign Application Priority Data
Mar. 2, 2015 (JP) 2015-40403

(51) Int. Cl. H01L 23/373; H01L 23/00; H01L 23/31

(52) U.S. Cl. CPC H01L 23/3735; H01L 23/3121; H01L 24/33; H01L 2224/32225; H01L 2224/32245; H01L 2224/33181; H01L 2924/13091; H01L 2924/13055; H01L 2924/10253; H01L 2924/10272; H01L 2924/1033; H01L 2924/17724; H01L 2924/17747; H01L 2924/1776; H01L 2924/186; H01L 2924/0665

(57) ABSTRACT

An electronic device includes: a heating element; an insulation metal component; and a sealing component. The insulation metal component includes a first metal part to which the heating element is mounted, a second metal part having a portion exposed from the sealing component, and an insulation part interposed between the first metal part and the second metal part. The second metal part has a central part and a peripheral part having a thickness thinner than that of the central part. The second metal part has one surface opposing and in tight contact with the insulation part, and an exposed surface opposite from the sealing component within an area corresponding to the central part. The second metal part has a recess recessed from a virtual straight line that connects an end of the one surface to an end of the exposed surface at a shortest distance around the central part.

### CROSS REFERENCE TO RELATED APPLICATION

This application is based on Japanese Patent Application No. 2015-40403 filed on Mar. 2, 2015, the disclosure of which is incorporated herein by reference.

### TECHNICAL FIELD

The present disclosure relates to an electronic device including an insulation metal component sealed by a sealing component.

### BACKGROUND ART

Patent Literature 1 describes a semiconductor module as an example of an electronic device, conventionally, including an insulation metal component sealed by a sealing component.

The semiconductor module has a heat spreader, a semiconductor device mounted on the upper surface side of the heat spreader, an insulation layer bonded on the undersurface of the heat spreader, a metal sheet layer bonded on the undersurface of the insulation layer, and a resin mold which covers them. The undersurface of the metal sheet layer is exposed from the resin mold, in the semiconductor module. The metal sheet layer is located at the central part of the undersurface of the heat spreader, while an area of the metal sheet layer is smaller than an area of the insulation layer covering the undersurface of the heat spreader.

### PRIOR ART LITERATURES

### Patent Literature

Patent Literature 1: JP 2010-287827 A

### SUMMARY OF INVENTION

In the semiconductor module, a resin mold may exfoliate from a metal sheet, depending on a difference in coefficient of linear expansion between the metal sheet and the resin mold. However, since the metal sheet layer is smaller in area than the insulating layer, even if the resin mold begins to exfoliate from the metal sheet layer, the advance of exfoliation can be stopped in the insulating layer, such that the exfoliation is restricted from reaching a heat spreader.

However, in the semiconductor module, since the advance of exfoliation is restricted in the insulating layer, a stress is applied to the insulating layer when the resin mold exfoliates. A crack may be generated in the insulating layer due to the stress applied from the resin mold. If the insulating layer is cracked, a heat spreader is exposed from the crack. In this case, the semiconductor module cannot secure the insulation by the insulating layer.

The present disclosure is aimed to provide an electronic device in which insulation is secured, while advance of exfoliation is restricted.

According to an aspect of the present disclosure, an electronic device includes:
a heating element that emits heat by operating;
an insulation metal component to which the heating element is mounted, the insulation metal component radiating heat of the heating element; and
a sealing component that seals the heating element and the insulation metal component.

The insulation metal component includes a first metal part to which the heating element is mounted, a second metal part having a portion exposed from the sealing component, and an insulation part interposed between the first metal part and the second metal part to be insulated from each other in a stacked manner.

The second metal part has a central part and a peripheral part surrounding the central part. The peripheral part has a thickness thinner than that of the central part, and the sealing component seals the peripheral part. The second metal part has one surface opposing and in tight contact with the insulation part, and an exposed surface opposite from the one surface and exposed from the sealing component within an area corresponding to the central part. The second metal part has a recess recessed than a virtual straight line that connects an end of the one surface to an end of the exposed surface at a shortest distance around the central part.

Depending on the difference in coefficient of linear expansion between the second metal part and the sealing component, the sealing component may exfoliate from the second metal part. When the sealing component begins to exfoliate from the second metal part, the exfoliating starts from a boundary part between the sealing component and the second metal part. That is, the boundary part may be a starting point of exfoliation between the sealing component and the second metal part. In addition, the boundary part is an end of an interface between the sealing component and the second metal part, adjacent to the exposed surface.

However, the second metal part has the peripheral part surrounding the central part and sealed by the sealing component, and the thickness of the peripheral part is thinner than that of the central part. The second metal part has the recess recessed than the virtual straight line, around the central part. For this reason, if the sealing component begins to exfoliate from the boundary part, the exfoliation easily stops once at a place where the exfoliation reaches a part of the recess. Therefore, when the sealing component begins to exfoliate from the boundary part, the exfoliation is restricted from advancing to the first metal part.

Furthermore, when the exfoliation stops at the place around the recess, a stress is restricted from being applied to the insulation part, while the sealing component exfoliates. Therefore, a cracking caused by the stress from the sealing component can be restricted in the insulation part. For this reason, the insulation property can be secured by the insulation part.

### BRIEF DESCRIPTION OF DRAWINGS

The above and other objects, features and advantages of the present disclosure will become more apparent from the following detailed description made with reference to the accompanying drawings. In the drawings:

FIG. 1 is a sectional view illustrating a schematic configuration of an electronic device according to an embodiment.

FIG. 2 is a plan view seen from a substrate side and illustrating the schematic configuration of the electronic device of the embodiment.

FIG. 3 is a plan view seen from a back side and illustrating the schematic configuration of the electronic device of the embodiment.

FIG. 4 is a sectional view illustrating a schematic partial configuration of a second metal part in the embodiment.

FIG. 5 is a sectional view illustrating a schematic partial configuration of a second metal part according to a first modification.

FIG. 6 is a sectional view illustrating a schematic partial configuration of a second metal part according to a second modification.

FIG. 7 is a sectional view illustrating a schematic partial configuration of a second metal part according to a third modification.

FIG. 8 is a sectional view illustrating a schematic partial configuration of a second metal part according to a fourth modification.

FIG. 9 is a sectional view illustrating a schematic configuration of an electronic device according to a fifth modification.

FIG. 10 is a plan view seen from a back side and illustrating the schematic configuration of the electronic device of the fifth modification.

### DESCRIPTION OF EMBODIMENTS

Embodiments will be described hereafter referring to drawings. In the embodiments, a part that corresponds to a matter described in a preceding embodiment may be assigned with the same reference numeral, and redundant explanation for the part may be omitted. When only a part of a configuration is described in an embodiment, another preceding embodiment may be applied to the other parts of the configuration.

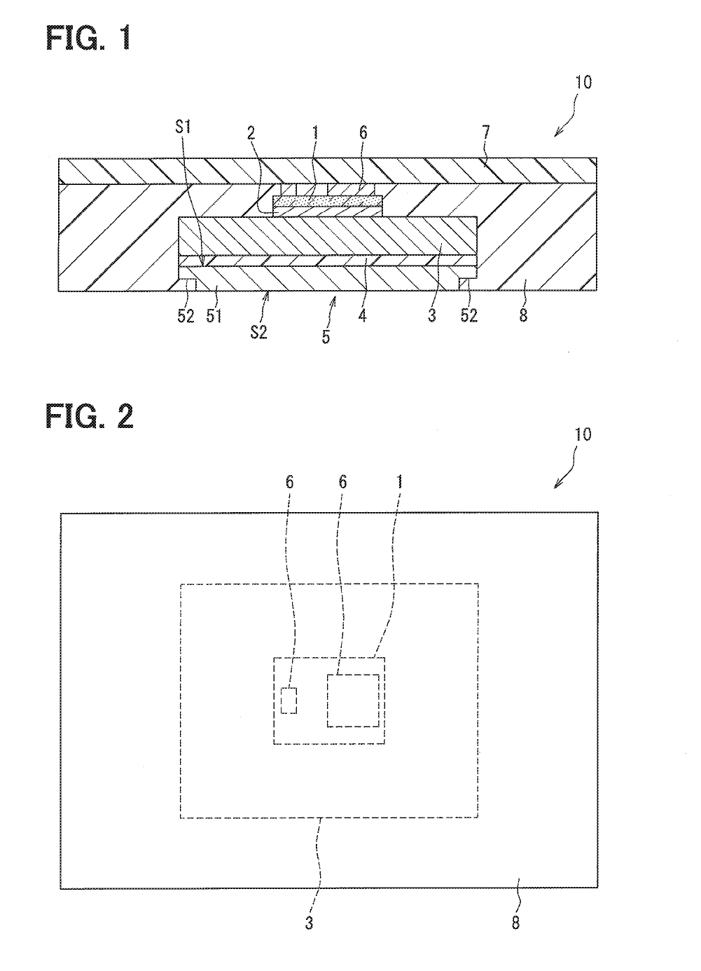

As shown in FIG. 1, an electronic device 10 has a semiconductor device 1, a circuit board 7, a mold resin 8, and an insulation metal component. The electronic device 10 is applicable to, for example, a power converter.

The semiconductor device 1 is an element which emits heat by operating, and is equivalent to a heating element such as MOSFET, IGBT, or reverse conducting type IGBT. The semiconductor device 1 may be an element mainly made of S1, an element mainly made of SiC, or an element mainly made of GaN. A gate electrode and an emitter electrode are formed on a surface of the semiconductor device 1, and a collector electrode is formed on the opposite surface. The collector electrode is larger in area than the gate electrode or the emitter electrode. The area means an area of a surface along the formation surface of the gate electrode or the emitter electrode, or the formation surface of the collector electrode in the semiconductor device 1.

The semiconductor device 1 is mounted on the circuit board 7, for example, in the bare chip state. The semiconductor device 1 may be called as a power element. The semiconductor device 1 may be an element having a gate electrode and an emitter electrode formed on a surface, and a collector electrode formed on the other surface.

The semiconductor device 1 is mounted to the circuit board 7 through a jointing material 6. Specifically, each of the gate electrode and the emitter electrode of the semiconductor device 1 is electrically and mechanically connected with the circuit board 7 through the jointing material 6. Moreover, the semiconductor device 1 is mounted to the insulation metal component through a jointing material 2. The collector electrode of the semiconductor device 1 is electrically and mechanically connected with a first metal part 3 of the insulation metal component through the jointing material 2. The semiconductor device 1 has a mounting surface mounted to the first metal part 3, and an opposite surface opposite from the mounting surface, and the semiconductor device 1 is mounted to the circuit board 7 in the state where the opposite surface opposes the circuit board 7. The jointing material 2, 6 is a conductive jointing material such as solder, silver paste or metal sintered compact.

The circuit board 7 has a land and a wiring formed on an insulated base such as resin or ceramics, with conductive patterns such as Cu. The semiconductor device 1 is mounted on and is electrically connected with the circuit board 7. The circuit board 7 may be a stacked substrate in which conductive patterns are stacked through an insulated base. The circuit board 7 may be a leadframe mainly made of, for example, Cu, Al, or Fe. As mentioned above, in the electronic device 10, the circuit board 7 is electrically connected to the semiconductor device 1. Therefore, when most of required circuit wiring is formed on the circuit board 7, the first metal part 3 can be made to have a shape with priority to the heat radiating property.

The mold resin 8 is equivalent to a sealing component. The mold resin 8 is made of, for example, epoxy resin as a main ingredient, and can be formed by compression molding, transfer molding, and the like. The mold resin 8 seals the semiconductor device 1 and the insulation metal component. Furthermore, the mold resin 8 also covers a mounting surface of the circuit board 7 where the semiconductor device 1 is mounted, and the jointing material 2, 6. That is, the mold resin 8 covers and in tight contact with the semiconductor device 1, the mounting surface of the circuit board 7, the jointing material 2, 6, and the insulation metal component. To be explained later, a part of the insulation metal component is exposed from the mold resin 8. Therefore, the mold resin 8 is formed to cover a part of the insulation metal component.

The insulation metal component is configured to include the first metal part 3, the insulation part 4, and the second metal part 5. Specifically, the insulation metal component is defined by stacking the first metal part 3 on which the semiconductor device 1 is mounted, the second metal part 5 having a portion exposed from the mold resin 8, and the insulation part 4 interposed between the first metal part 3 and the second metal part 5. As shown in FIG. 1, the insulation metal component is defined by stacking in order of the first metal part 3, the insulation part 4, and the second metal part 5 relative to the semiconductor device 1. The insulation metal component to which the semiconductor device 1 is mounted is a component which radiates heat emitted from the semiconductor device 1. Therefore, the insulation metal component functions as a heat sink for the semiconductor device 1.

The first metal part 3 is a heat sink for radiating heat of the semiconductor device 1 to the exterior in diffused manner. The first metal part 3 may be mainly made of, for example, Cu, Al, Mo, or Fe, or composite material of Cu, Al, Mo, and Fe. In this embodiment, the first metal part 3 is made of Cu as a main ingredient as an example. As shown in FIG. 2, the first metal part 3 is located to oppose the semiconductor device 1. The first metal part 3 is electrically connected to the collector electrode of the semiconductor device 1 through the jointing material 2. The insulation part 4 is in tight contact with the first metal part 3 on the back side opposite from the semiconductor device 1.

As shown in FIG. 1 and FIG. 2, the first metal part 3 is a rectangular parallelepiped block object, and has a plane form. Therefore, the surface of the first metal part 3 opposing the insulation part 4 is made into rectangle form. However, the form of the first metal part 3 is not limited to this. The first metal part 3 may have, for example, a pillar form. In addition, the first metal part 3 may have a non-illustrated terminal for external connection, such that the electronic device 10 is electrically connected to an external apparatus.

The insulation part 4 is a component for transmitting heat of the first metal part 3 to the second metal part 5, while the first metal part 3 and the second metal part 5 are electrically insulated from each other by the insulation part 4. That is, the first metal part 3 to which the collector electrode of the semiconductor device 1 is electrically connected is electrically insulated from the second metal part 5 having a portion exposed from the mold resin 8, by the insulation part 4 for transmitting heat transmitted to the first metal part 3 from the semiconductor device 1 to the second metal part 5. For this reason, the insulation part 4 is desirably made of high radiation and insulation resin layer which has high thermal conductivity and insulation property. The insulation part 4 may be made of composite material of, for example, epoxy-base resin and ceramic filler. A surface of the insulation part 4 opposing the first metal part 3 and a surface of the insulation part 4 opposing the second metal part 5 have rectangle form, for example. However, the form of the insulation part 4 is not limited to this. The insulation part 4 may have, for example, a round shape. Moreover, since the insulation part 4 is in tight contact with each of the first metal part 3 and the second metal part 5, it is desirable to have the same form as the form of a surface of the first metal part 3 opposing the insulation part 4 and the form of a surface of the second metal part 5 opposing the insulation part 4.

According to the present embodiment, the surface area of the insulation part 4 opposing the first metal part 3 is the same as the surface area of the first metal part 3 opposite from the semiconductor device 1. Furthermore, in this embodiment, the surface area of the insulation part 4 opposing one surface S1 is the same as the surface area of the one surface S1.

Moreover, the insulation part 4 is desirably provided to be in tight contact with all the area of the first metal part 3 opposite from the semiconductor device 1 and all the one surface S1 of the second metal part 5 to be explained later, By this, the insulation part 4 can efficiently transfer heat from the first metal part 3 to the second metal part 5.

The second metal part 5 is a heat sink for radiating heat of the semiconductor device 1 to the exterior, in diffused manner. The second metal part 5 may be mainly made of Cu, Al, Mo, or Fe as a main ingredient, and may be made of composite material of Cu, Al, Mo, and Fe. In this embodiment, the second metal part 5 is made of Cu as a main ingredient as an example.

As shown in FIG. 1 and FIG. 2, the second metal part 5 has the central part 51 and the peripheral part 52 surrounding the central part 51. A thickness of the peripheral part 52 is thinner than that of the central part 51. The thickness of the second metal part 5 means thickness of the first metal part 3, the insulation part 4, and the second metal part 5 in the stacking direction. The stacking direction of the first metal part 3, the insulation part 4, and the second metal part 5 may be referred to just a stacking direction.

The one surface S1 or the second metal part 5 opposes the insulation part 4, and is in tight contact with the insulation part 4. A part of the opposite surface opposite from the one surface S1 is exposed from the mold resin 8. Moreover, the one surface S1 of the second metal part 5 is in tight contact with all the surface of the insulation part 4 opposing the one surface S1. That is, the whole surface of the insulation part 4 opposing the one surface S1 is covered by the second metal part 5, For this reason, according to the electronic device 10, the tightness between the insulation part 4 and the second metal part 5 can be improved, such that the heat transfer property can be improved, compared with a case where the one surface S1 is in tight contact with a part of the insulation part 4. However, the one surface S1 is not limited to this but may be just in contact with at least a part of the insulation part 4. In addition, in this embodiment, the area of the one surface S1 is the same, for example, as the surface area of the insulation part 4 opposing the one surface S1. Moreover, in this embodiment, the surface areas of the first metal part 3 and the insulation part 4 opposing to each other are the same.

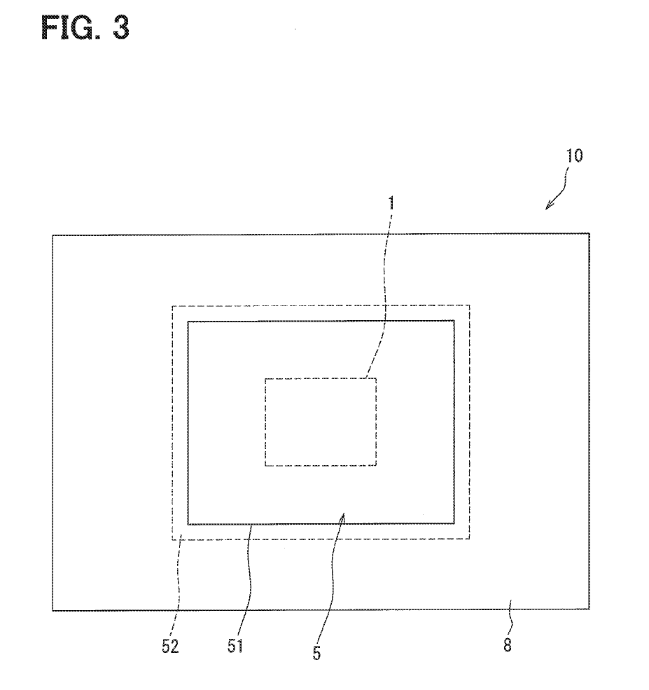

Moreover, a surface of the central part 51 opposing the insulation part 4 and a surface of the peripheral part 52 opposing the insulation part 4 correspond to the one surface S1, and are formed flush. The one surface S1 has a rectangle form. That is, a dashed line in FIG. 3 indicating the peripheral part 52 is considered to indicate the one surface S1. However, the one surface S1 is not limited to this, but may have, for example, a round shape.

As shown in FIG. 3, the second metal part 5 has the central part 51 and the peripheral part 52, for example, so that each side of the one surface S1 and each side of the exposed surface S2 to be later explained are in parallel spatial relationship. In the following description, the surface of the second metal part 5 opposite from the one surface S1 is also referred to an opposite surface of the second metal part 5.

The central part 51 has a rectangular parallelepiped shape, as shown in FIG. 1 and FIG. 3, and the opposite surface of the central part 51 defines the exposed surface S2 exposed from the mold resin 8. That is, the exposed surface S2 is a section corresponding to the central part 51 of the second metal part 5, on the opposite surface. As shown in FIG. 3, the exposed surface S2 has rectangle form. However, the central part 51 is not limited to this, but may have, for example, a pillar shape. Moreover, the exposed surface S2 may, for example, have a round shape. That is, the exposed surface S2 may have a form corresponding to the form of the central part 51.

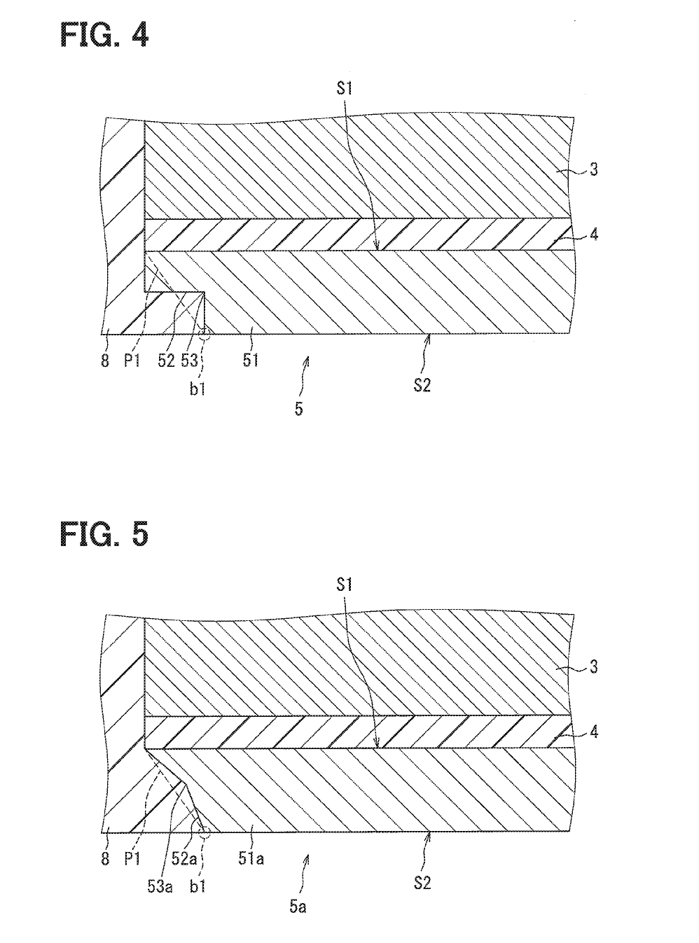

As shown in FIG. 1 and FIG. 4, the exposed surface S2 is flush with the surface of the mold resin 8 around the exposed surface S2. Therefore, according to the electronic device 10, a part of the mold resin 8 is formed flush with the exposed surface S2.

The peripheral part 52 is covered with the mold resin 8, as shown in FIG. 1 and FIG. 3. That is, the section of the opposite surface of the second metal part 5 corresponding to the peripheral part 52 is covered by the mold resin 8. The peripheral part 52 can be defined to project from the side wall of the central part 51 all the circumferences, as a flange part. Moreover, since the peripheral part 52 surrounds all the peripheries of the central part 51, the peripheral part 52 can also be referred to an annular part. Furthermore, the second metal part 5 can be said to have the peripheral part 52 recessed from the exposed surface S2, around the exposed surface S2.

The exposed surface S2 is a section of the opposite surface of the second metal part 5 corresponding to the central part 51. In contrast, the one surface S1 is a section formed of a surface of the central part 51 opposing the insulation part 4 and a surface of the peripheral part 52 opposing the insulation part 4. For this reason, the area of the one surface S1 is larger than the area of the exposed surface S2.

As shown in FIG. 4, the second metal part 5 has a recess part recessed than a virtual straight line P1 which connects the end of the one surface S1 to the end of the exposed surface S2 at the shortest distance, around the central part 51. In the electronic device 10, an angle part 53 defined between the central part 51 and the peripheral part 52 is included in the recess part recessed from the virtual straight line P1. That is, the electronic device 10 has the recess part recessed than the virtual straight line P1, in the cross-section crossing the stacking direction along the virtual straight line P1.

In the electronic device 10 configured in this way, depending on a difference in coefficient of linear expansion between the second metal part 5 and the mold resin 8, the mold resin 8 may exfoliate from the second metal part 5. The mold resin 8 begins to exfoliate from the second metal part 5, starting at the boundary part b1 between the mold resin 8 and the second metal part 5. That is, the boundary part b1 can serve as a starting point of exfoliation between the mold resin 8 and the second metal part 5.

However, in this embodiment, the peripheral part 52 is provided to surround the central part 51 and to be sealed by the mold resin 8, and the thickness of the peripheral part 52 is thinner than that of the central part 51. The recess part recessed from the virtual straight line P1 is formed adjacent to the central part 51. For this reason, according to the electronic device 10, if the mold resin 8 begins to exfoliate from the boundary part b1, the exfoliation easily once stops at the place reaching a part of the recess part recessed than the virtual straight line P1. In this embodiment, the angle part 53 is formed as a part of the recess part recessed than the virtual straight line P1. Therefore, the exfoliation of the mold resin 8 easily once stops at the angle part 53. Thus, according to the electronic device 10, if the mold resin 8 begins to exfoliate from the boundary part b1, the exfoliation can be restricted from advancing. That is, the exfoliation of the mold resin 8 can be restricted from reaching the first metal part 3 and the insulation part 4.

Furthermore, according to the electronic device 10, when the exfoliation stops once at the angle part 53, the stress generated when the mold resin 8 exfoliates is hard to be applied to the insulation part 4. That is, although a stress caused by contraction of the mold resin 8 is applied to the second metal part 5, the stress is difficult to be applied to the insulation part 4. Therefore, according to the electronic device 10, a cracking can be restricted from being generated in the insulation part 4 by the stress from the mold resin 8. For this reason, the electronic device 10 can secure the insulation by the insulation part 4. Moreover, since a crack can be restricted in the electronic device 10, the first metal part 3 electrically connected with the semiconductor device 1 can be restricted from being exposed to the exfoliated area of the mold resin 8. In other words, the electronic device 10 is equipped with the insulation metal component with high insulation reliability.

In the above, the embodiment is described. However, the present disclosure can be implemented with various modifications, not restricted to the embodiment, in the range not deviate from the present disclosure. Hereafter, first to fourth modifications are explained. It is possible to solely implement the embodiment and the first to fourth modifications or to suitably combine the embodiment and the first to fourth modifications. The present disclosure can be carried out with various combinations, without being limited to the combination shown in the embodiment.

### First Modification

An electronic device according to a first modification is explained using FIG. 5. Here, description is made at points different from the embodiment. Explanation is omitted about points similar to the embodiment, by giving the same mark as the embodiment. The electronic device of the first modification differs from the embodiment in the configuration of the second metal part 5a of an insulation metal component. In addition, although the central part 51a of the second metal part 5a is the same as the central part 51, the mark is changed.

As shown in FIG. 5, the peripheral part 52a is sealed by the mold resin 8 like the peripheral part 52. Moreover, an area of the one surface S1 is larger than the area of the exposed surface S2 in the second metal part 5a like the second metal part 5. In addition, the same material can be used for the second metal part 5a as the second metal part 5.

The second metal part 5a is different from the second metal part 5 in the form of the peripheral part 52a. In other words, the second metal part 5a differs from the second metal part 5 in the form of the side wall. The peripheral part 52a has the form inclined in two steps relative to the exposed surface S2. An angle defined between the peripheral part 52a and the exposed surface S2 is smaller on the inclination side adjacent to the exposed surface S2 than the inclination side adjacent to the insulation part 4. In other words, the peripheral part 52a has a first inclination part and a second inclination part from the side of the exposed surface S2. An angle defined between the first inclination part and the exposed surface S2 is smaller than the angle defined between the second inclination part and the exposed surface 62. Thus, the second metal part 5a has the recess part recessed than the virtual straight line P1, around the central part 51a, similarly to the second metal part 5. An intermediate part 53a of the second metal part 5a between the first inclination part and the second inclination part is included in the recess part recessed than the virtual straight line P1.

According to the electronic device of the first modification, if the mold resin 8 begins to exfoliate from the boundary part b1, the exfoliation once easily stops at the place arriving at the intermediate part 53a. For this reason, the electronic device of the first modification achieves the same effect as the electronic device 10.

Moreover, the second metal part 5a can be formed by etching. It is easier to form the second metal part 5a than the second metal part 5 by etching, since the peripheral part 52a is inclined.

### Second Modification

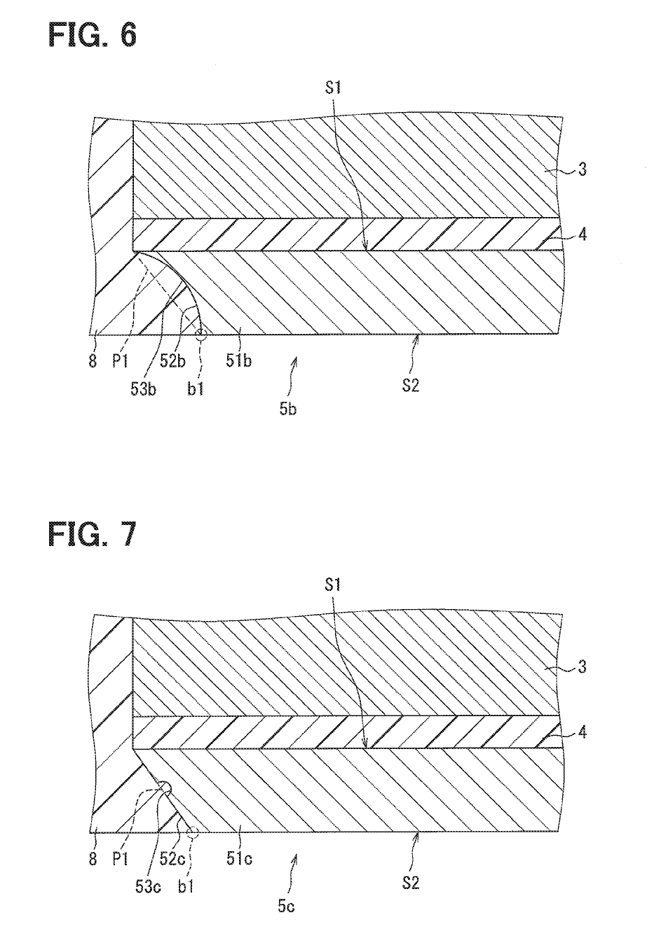

An electronic device according to a second modification is explained using FIG. 6. Here, description is made at points different from the embodiment. Explanation is omitted about points similar to the embodiment, by giving the same mark as the embodiment. The electronic device of the second modification differs from the embodiment in the configuration of the second metal part 5b of an insulation metal component. In addition, although the central part 51b of the second metal part 5b is the same as the central part 51, the mark is changed.

As shown in FIG. 6, the peripheral part 52b is sealed by the mold resin 8 like the peripheral part 52. Moreover, an area of the one surface S1 is larger than the area of the exposed surface S2 in the second metal part 5b like the second metal part 5. In addition, the same material can be used for the second metal part 5b as the second metal part 5.

The second metal part 5b is different from the second metal part 5 in the form of the peripheral part 52b. In other words, the second metal part 5b differs from the second metal part 5 in the form of the side wall. The peripheral part 52b has a curved surface form curved from the end of the exposed surface S2 to the end of the one surface S1. Moreover, the cross-sectional area of the second metal part 5b parallel to the exposed surface S2 becomes gradually large as going to the one surface S1 from the exposed surface S2. Therefore, the second metal part 5b has the recess part recessed than the virtual straight line P1 around the central part 51b like the second metal part 5. For example, a middle point 53b of the peripheral part 52b of the second metal part 5b is included in the recess part recessed than the virtual straight line P1.

According to the electronic device of the second modification, if the mold resin 8 begins to exfoliate from the boundary part b1, the exfoliation easily once stops at the place arriving at the middle point 53b of the peripheral part 52b. For this reason, the electronic device of the second modification achieves the same effect as the electronic device 10.

Moreover, the second metal part 5b can be formed by etching. It is easier to form the second metal part 5b than the second metal part 5 by etching, since the peripheral part 52b has the curved surface form.

### Third Modification

An electronic device according to a third modification is explained using FIG. 7. Here, description is made at points different from the embodiment. Explanation is omitted about points similar to the embodiment, by giving the same mark as the embodiment. The electronic device of the third modification differs from the embodiment in the configuration of the second metal part 5c in an insulation metal component. In addition, although the central part 51c of the second metal part 5c is the same as the central part 51, the mark is changed.

As shown in FIG. 7, the peripheral part 52c is sealed by the mold resin 8 like the peripheral part 52. Moreover, an area of the one surface S1 is larger than the area of the exposed surface S2 in the second metal part 5c like the second metal part 5. In addition, the same material as the second metal part 5 can be used for the second metal part 5c.

The second metal part 5c differs from the second metal part 5 in the form of the peripheral part 52c. In other words, the second metal part 5c differs from the second metal part 5 in the form of the side wall, The peripheral part 52c inclines to the exposed surface S2, and a concave portion 53c is formed in the middle of the inclination. Moreover, the angle defined between the peripheral part 52c and the exposed surface S2 is larger than 90 degrees. Thus, the second metal part 5c has the concave portion 53c recessed than the virtual straight line P1, like the second metal part 5, around the central part 51c.

According to the electronic device of the third modification, if the mold resin 8 begins to exfoliate from the boundary part b1, the exfoliation easily once stops at the place reaching the concave portion 53c of the peripheral part 52b. For this reason, the electronic device of the third modification achieves the same effect as the electronic device 10. Furthermore, since the concave portion is formed in the peripheral part 52b, the exfoliation of the mold resin 8 can be further restricted in the electronic device 10.

### Fourth Modification

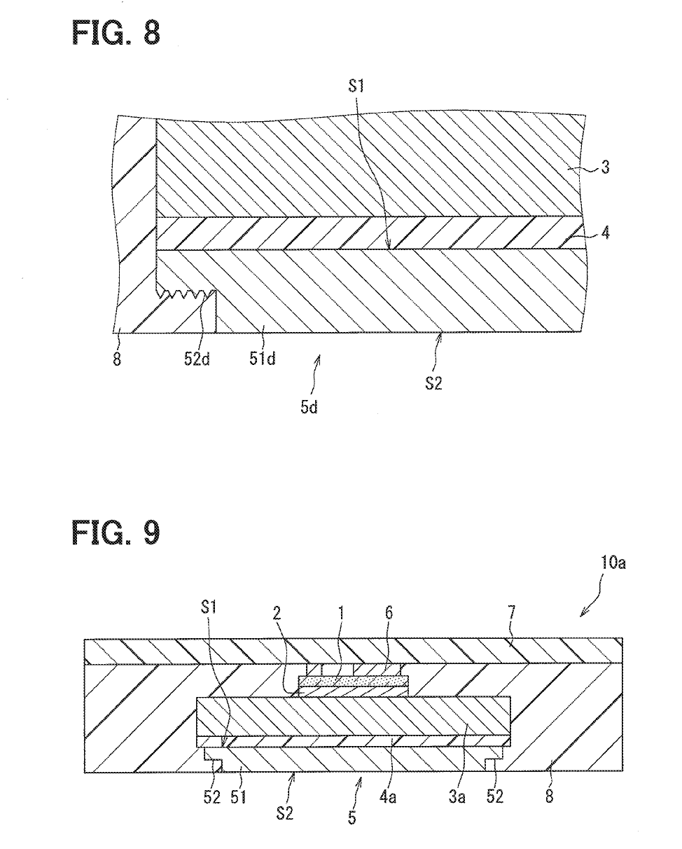

An electronic device according to a fourth modification is explained using FIG. 8. Here, description is made at points different from the embodiment. Explanation is omitted about points similar to the embodiment, by giving the same mark as the embodiment. The electronic device of the fourth modification differs from the embodiment in the configuration of the second metal part 5d in an insulation metal component. In addition, although the central part 51d of the second metal part 5d is the same as the central part 51, the mark is changed.

As shown in FIG. 8, the peripheral part 52d is sealed by the mold resin 8 like the peripheral part 52. Moreover, an area of the one surface S1 is larger than the area of the exposed surface S2 in the second metal part 5d like the second metal part 5. In addition, the same material as the second metal part 5 can be used for the second metal part 5d.

The peripheral part 52d has a coarse surface. In other words, the surface of the peripheral part 52d has an uneven form. The electronic device of the fourth modification achieves the same effect as the electronic device 10. Furthermore, since the peripheral part 52d has the rough surface form, the peripheral part 52d has a contact surface area with the mold resin 8 that is larger than the peripheral part 52, such that the exfoliation can be further restricted in the electronic device of the fourth modification.

### Fifth Modification

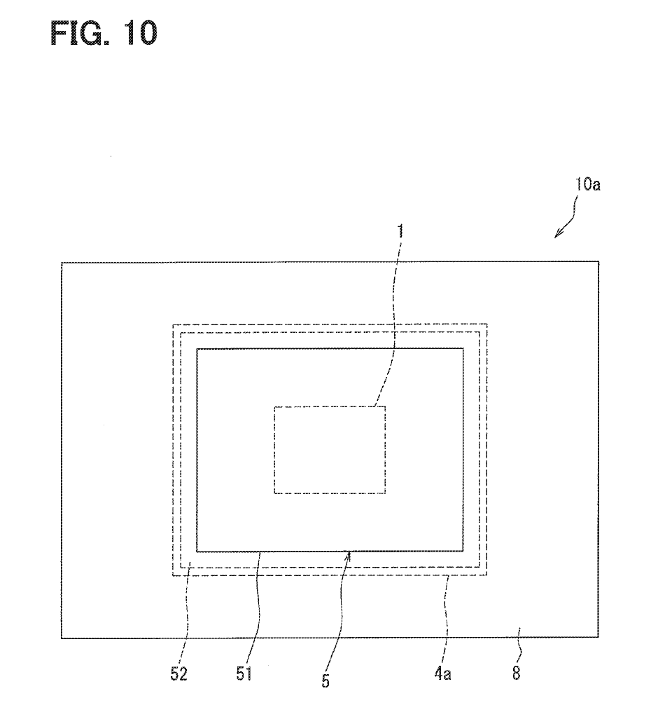

An electronic device 10a according to a fifth modification is explained using FIG. 9 and FIG. 10. Here, description is made at points different from the embodiment. Explanation is omitted about points similar to the embodiment, by giving the same mark as the embodiment. The electronic device 10a differs from the embodiment in the configuration of the first metal part 3a and the insulation part 4a in an insulation metal component.

As shown in FIG. 9 and FIG. 10, according to the electronic device 10a, a surface area of the insulation part 4a opposing the one surface S1 is larger than the surface area of the one surface S1. Moreover, according to the electronic device 10a, the surface area of the insulation part 4a opposing the first metal part 3a is the same as the surface area of the first metal part 3a opposite from the semiconductor device 1. In addition, the same material as the first metal part 3 can be used for the first metal part 3a, and the same material as the insulation part 4 can be used for the insulation part 4a. The electronic device 10a achieves the same effect as the electronic device 10.

1. An electronic device comprising:
a heating element that emits heat by operating;
an insulation metal component to which the heating element is mounted, the insulation metal component radiating heat of the heating element; and
a sealing component that seals the heating element and the insulation metal component, wherein
the insulation metal component includes
a first metal part to which the heating element is mounted,
a second metal part having a portion exposed from the sealing component, and
an insulation part interposed between the first metal part and the second metal part to be insulated from each other in a stacked manner,
the second metal part has a central part and a peripheral part surrounding the central part, the peripheral part having a thickness thinner than that of the central part, the sealing component sealing the peripheral part,
the second metal part has one surface opposing and in tight contact with the insulation part, and an exposed surface opposite from the one surface, the exposed surface being exposed from the sealing component within an area corresponding to the central part, and
the second metal part has a recess recessed than a virtual straight line that connects an end of the one surface to an end of the exposed surface at a shortest distance around the central part.

2. The electronic device according to claim 1, wherein
the peripheral part has a coarse surface.

3. The electronic device according to claim 1, further comprising:
a circuit board to which the heating element is mounted, the circuit board being electrically connected with the heating element,
the heating element has a mounting surface mounted to the first metal part, and an opposite surface opposite from the mounting surface, and the heating element is mounted to the circuit board in a state where the opposite surface opposes the circuit board, and
the sealing component seals a mounting surface of the circuit board to which the heating element is mounted.

4. The electronic device according to claim 1, wherein
the one surface of the second metal part is in tight contact with all surface area of the insulation part opposing the one surface.
